(19) United States
(12) Patent Application Publication
(10) Pub. No.: US 2007/0182566 A1
(43) Pub. Date: Aug. 9, 2007

(54) Mobile device having RFID system

(75) Inventors: Yong-jin Kim, Seoul (KR); Young-eil Kim, Suwon-si (KR); Seong-soo Lee, Suwon-si (KR); Hyung-min Yoon, Seoul (KR); Ick-jae Yoon, Seoul (KR); Ji-hun Koo, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/588,396

(22) Filed: Oct. 27, 2006

(30) Foreign Application Priority Data
Feb. 3, 2006 (KR) 10-2006-0010502

(51) Int. Cl. G08B 13/14; H05K 11/00

(52) U.S. Cl. 340/572.8; 455/344

(57) ABSTRACT

A mobile communication terminal has a radio frequency identification (RFID) system to read information from RFID tags at predetermined distances. An RFID transmission antenna to transmit or receive a wireless signal for mobile communication to/from a base station, or transmit wireless signal to the RFID tag, and an RFID reception antenna to receive RFID wireless signal transmitted from the RFID tag. Accordingly, ingress of the RFID transmission carrier leakage to the RFID reception circuit can be prevented. Additionally, a small size antenna such as a chip ceramic antenna is used exclusively for RFID reception, and the RFID reception antenna is also used as a mobile communication antenna. As a result, the mobile communication terminal can be compact-sized, the size of transmission signal can be increased, and dynamic range increases without having to increase the sensitivity of the RFID tag, to extend the communication distance.

### CROSS-REFERENCE TO RELATED APPLICATION

This application claims priority from Korean Patent Application No. 10-2006-0010502, filed Feb. 3, 2006, in the Korean Intellectual Property Office, the entire contents of which are incorporated herein by reference.

### BACKGROUND OF THE INVENTION

1. Field of the Invention

Apparatuses consistent with the present invention relate to a mobile device having a radio frequency identification (RFID) system, and more particularly, to a mobile device having an RFID system which is capable of preventing input of transmission carrier leakage to a receiver circuit, and which can be provided in a compact size.

2. Description of the Prior Art

An RFID system generally includes a reader, an antenna, an electronic tag, a server, and a network. The reader reads out or stores information from or to the electronic tag, and the antenna exchanges data with the electronic tag according to predefined frequencies and protocols.

With the combination of the RFID system and mobile communications, new technologies and services such as mobile RFID (mRFID) system has been introduced. The mRFID system has electronic tag, reader, antenna and processing modules mounted on the mobile communication terminal to enable the terminal to read in information from other electronic tags and accordingly provide users with information services, or to transmit information of the mobile communication terminal to the other devices using the electronic tags mounted therein.

FIG. 1 is a schematic circuit diagram showing an RFID tag and an RFID reader of a conventional RFID system. As shown, the RFID reader 10 may include a transmission circuit 20, a reception circuit 25, a phase locked loop (PLL) 21, and a processing circuit 27.

The transmission circuit 20 generates a transmission signal of a predetermined frequency to be transmitted to the RFID tag 30, and the reception circuit 25 receives a reception signal which is the transmission signal reflected from the RFID tag 30.

The PLL 21 detects phase difference between the transmission signal and the reception signal, and accordingly controls the phase of the mixer with a voltage proportional to the detected phase difference so that the reception and the transmission signals can have the same phase.

The processing circuit 27 controls the transmission circuit 20 to transmit a transmission signal to the RFID tag 30, and analyzes the reception signal at the reception circuit 25 to acquire information of the RFID tag 30.

The transmission circuit 20 and the reception circuit 25 may include an antenna 11, a filter 13 and a DC coupling 15. The antenna 11 transmits the transmission signal from the transmission circuit 20 to the RFID tag 30, and receives the reception signal reflected from the RFID tag 30 and sends the received signal to the reception circuit 25. The filter 13 filters the transmission and reception signals to a desired size, and the DC coupling 15 adjusts DC voltage of the transmission and reception signals.

Meanwhile, a general mobile communication terminal has transmission and reception circuits which operate independently. Therefore, the signal transmitted from the transmission circuit and the signal received at the reception circuit have different frequencies. Because the reception circuit can be turned off when the transmission circuit operates, the transmission signal of the transmission circuit is prevented from being directly input to the reception circuit.

However, in an RFID system, a single antenna is used to transmit and receive signals. In particular, when the RFID system is applied to the mobile communication terminal, it is difficult to install a plurality of antennas due to space constraints. Furthermore, both the transmission circuit 20 and the reception circuit 25 use the same frequency in the RFID system, and they are kept in an on state at the same time because the distance to the RFID tag 30 is unidentified. Therefore, the Tx carrier leakage of the transmission signal from the transmission circuit 20 may be directly input to the reception circuit 25 over the antenna 11 or through the circuit.

If the Tx carrier leakage is input to the reception circuit 25, this will cause noise, and a mixed signal of a reception signal from the RFID tag 30 and the Tx carrier leakage is received at the reception circuit 25. Therefore, it is practically impossible to acquire an accurate reception signal from the RFID tag 30, and degradation of signal and direct current (DC) offset occur.

Some components of the reception circuit 25 such as a low-noise amplifier (LNA) or a mixer are designed to have low linearity, that is, they receive a small-size signal from the RFID tag 30. If the components receive a large Tx carrier leakage from the transmission circuit 20, the LNA of the reception circuit 25 may not operate due to saturation.

The Tx carrier leakage increases as the size of the transmission signal is larger. Therefore, it is difficult to increase the size of the signal. Because the read range of the RFID tag 30 decreases, communication distance between the RFID reader and the RFID tag is limited.

Meanwhile, an RFID antenna used in the mRFID technology transmits and receives wireless signal of 908.5˜914 MHz, but an antenna for the communication of the mobile communication terminal transmits and receives a wireless signal of 850 MHZ. Although the difference between the bands for an RFID wireless signal and the mobile communication signal is relatively small, it is hard for the mobile communication antenna, which is designed for narrow band, to transmit and receive an RFID wireless signal. Accordingly, the existing mobile communication terminal uses not only the mobile communication antenna, but also the RFID antenna to use the mRFID technology. As a result, the size of the mobile communication terminal is increased.

Accordingly, it is necessary to separately install transmission and reception antennas in an mRFID system to prevent the input of Tx carrier leakage into the reception circuit. It is also necessary to reduce the size of the mobile communication terminal, which has an RFID antenna and a mobile communication antenna, and a transmission and a reception antennas separately according to the conventional art.

### SUMMARY OF THE INVENTION

Illustrative, non-limiting embodiments of the present invention overcome the above disadvantages and other disadvantages not described above. Also, the present invention is not required to overcome the disadvantages described above, and an illustrative, non-limiting embodiment of the present invention may not overcome any of the problems described above.

The present invention provides a mobile communication terminal having an RFID system, which is capable of preventing input of a transmission carrier leakage into a reception circuit.

The present invention also provides a mobile communication terminal having an RFID system, which is capable of preventing size increase of the mobile communication terminal due to mounting of a plurality of antennas.

According to one aspect of the present invention, the present invention provides a mobile communication terminal comprising an RFID system to read information from an RFID tag arranged at a distance, the mobile communication terminal comprising an RFID transmission antenna which transmits or receives a wireless signal for mobile communication with a base station, and transmits a first RFID wireless signal to the RFID tag, and an RFID reception antenna which receives a second RFID wireless signal transmitted from the RFID tag.

The RFID transmission antenna may comprise at least one of a whip antenna, a planar inverted F antenna (PIFA), and a patch antenna.

The RFID transmission antenna is a main antenna, and is also used as a mobile communication antenna to transmit and receive a mobile communication wireless signal.

An RFID matching circuit, which changes an operational band of the main antenna to a frequency band to transmit an output of the first RFID wireless signal, and a communication matching circuit, which matches the operational band of the main antenna to a frequency band for the mobile communication wireless signal, may also be provided.

The RFID reception antenna may comprise a small size antenna.

The RFID reception antenna may comprise a chip ceramic antenna which is formed of a dielectric substance.

The RFID receipt antenna may comprise a small size antenna that is a type of a planar inverted-F antenna or an inverted-F antenna (PIFA/IFA).

The RFID transmission antenna and the RFID reception antenna may be connected to a same ground.

A slot may be extended from one side of the ground to remove coupling between the RFID transmission antenna and the RFID reception antenna.

The RFID reception antenna may be provided separately from the RFID transmission antenna.

The present invention also provides a mobile communication terminal comprising a radio frequency identification (RFID) system to read information from an RFID tag arranged at a distance, the mobile communication terminal comprising: a RFID transmission antenna which transmits a first RFID wireless signal to the RFID tag; and a RFID reception antenna which transmits or receives a wireless signal for mobile communication with a base station, and receives a second RFID wireless signal transmitted from the RFID tag.

The RFID reception antenna may comprise at least one of a whip antenna, a planar inverted F antenna (PIFA), and a patch antenna.

The RFID reception antenna is a main antenna, and is also used as a mobile communication antenna to transmit and receive a mobile communication wireless signal.

An RFID matching circuit, which changes an operational band of the main antenna to a frequency band to receive an output of the second RFID signal; and a communication matching circuit, which matches the operational band of the main antenna to a frequency band for the mobile communication wireless signal, may further be provided.

The RFID transmission antenna comprises a small size antenna.

The RFID transmission antenna may comprise a chip ceramic antenna which is formed of a dielectric substance.

The RFID transmission antenna may comprise a small size antenna that is a type of a planar inverted-F antenna or an inverted-F antenna (PIFA/IFA).

The RFID transmission antenna and the RFID reception antenna may be connected to a same ground.

A slot may be extended from one side of the ground to remove coupling between the RFID transmission antenna and the RFID reception antenna.

The RFID transmission antenna may be provided separately from the RFID transmission antenna.

### BRIEF DESCRIPTION OF THE DRAWINGS

The above objects and/or aspects of the present invention will become more apparent by describing in detail certain exemplary embodiments thereof with reference to the attached drawings, in which:

FIG. 1 is a schematic circuit diagram of an RFID tag and an RFID reader of a conventional RFID system;

FIG. 2 is a perspective view of an antenna area of a mobile communication terminal according to a first exemplary embodiment of the present invention;

FIG. 3 is a circuit diagram of a mobile communication terminal to transmit and receive an RFID wireless signal and a mobile communication wireless signal using one antenna disclosed by the Applicant in Korean Patent Application No. 10-2005-0120707, filed on Dec. 9, 2005;

FIG. 4A is a graphical representation of characteristic S11 of the main antenna of FIG. 2;

FIG. 4B is a graphical representation of characteristic S11 of the RFID reception antenna of FIG. 2;

FIG. 5 is a perspective view of an antenna area of a mobile communication terminal according to a second exemplary embodiment of the present invention;

FIG. 6A is a graphical representation of characteristic S11 when the communication matching circuit is operated to enable transmission and reception of mobile communication wireless signal over the main antenna of FIG. 5;

FIG. 6B is a graphical representation of characteristic S11 when the RFID matching circuit is operated to enable transmission and reception of an RFID wireless signal over the main antenna of FIG. 5; and

FIG. 7 is a perspective view of an antenna area of a mobile communication terminal according to a third exemplary embodiment of the present invention.

### DETAILED DESCRIPTION OF THE EXEMPLARY EMBODIMENTS

Hereinafter, the present invention will be described in detail with reference to the drawings.

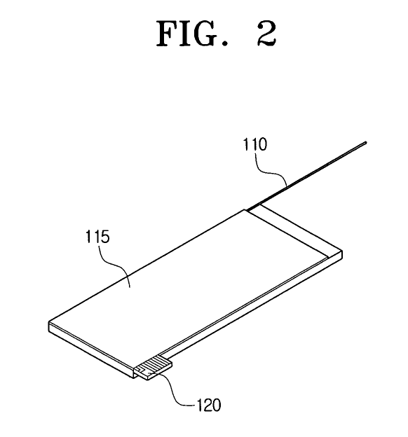

FIG. 2 is a perspective view of an antenna area of a mobile communication terminal according to a first exemplary embodiment of the present invention. As shown, the mobile communication terminal may include a main antenna 110, a ground 115 and an RFID reception antenna 120.

The main antenna 110 may be used as a mobile communication antenna which transmits and receives wireless communication signal when the mobile communication terminal operates in a basic communication mode. Alternatively, the main antenna 110 may be used as an RFID transmission antenna to transmit an RFID signal to the RFID tag.

The main antenna 110 may be implemented as any adequate antenna. In the first exemplary embodiment of the present invention, a whip antenna of a bar configuration will be used as the main antenna 110. The whip antenna is generally used in mobile communication terminals, and includes monopole antennas, dipole antennas and helical antennas. When implemented as a monopole antenna, a ground 115 is formed in the substrate of the mobile communication terminal, with an overall length of approximately λ/4.

A variety of ways are currently used to enable the use of the main antenna 110 both for mobile communication and RFID transmission. According to KR2005-120707, separate matching circuits may be employed to use one antenna for mobile communication and RFID.

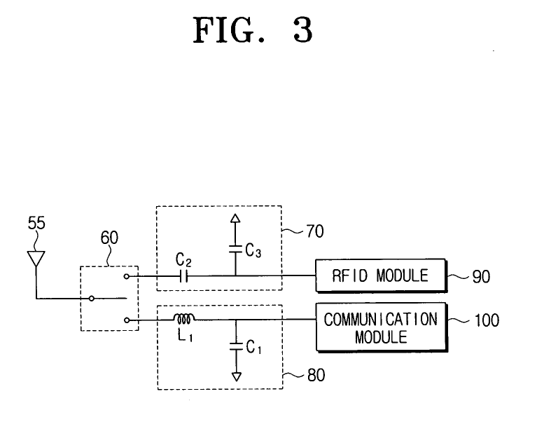

FIG. 3 is a circuit diagram of a mobile communication terminal to transmit and receive an RFID wireless signal and a mobile communication wireless signal using one antenna of KR2005-120707. As shown, the mobile communication terminal of KR2005-120707 includes a common antenna 55, a switch 60, an RFID matching circuit 70, a communication matching circuit 80, an RFID module 90 and a communication module 100.

The mobile communication terminal of KR2005-120707 includes a communication matching circuit 80 and an RFID matching circuit 70 separately, to transmit and receive both a wireless signal for mobile communication and a wireless signal for RFID.

The communication matching circuit 80 adjusts the operational band of the antenna 55 such that the operational band of the antenna 55 can match exactly the frequency band of the mobile communication wireless signal. The communication matching circuit 80 may be implemented with a variety of elements, and in this particular exemplary embodiment, the communication matching circuit 80 includes an inductor L1 in series connection with the antenna 55, and a capacitor C1 in parallel connection with the inductor L1.

The RFID matching circuit 70 may include a pair of capacitors C2, C3 in parallel connection with each other. One C2 of the capacitors is in series connection with the antenna 55, and the other one C3 of the capacitors is in parallel connection with the capacitor C2. The RFID matching circuit 70 moves the operational band of the antenna 55 matching the frequency band of the mobile communication wireless signal by a predetermined width so that the antenna 55 transmits and receives an RFID wireless signal.

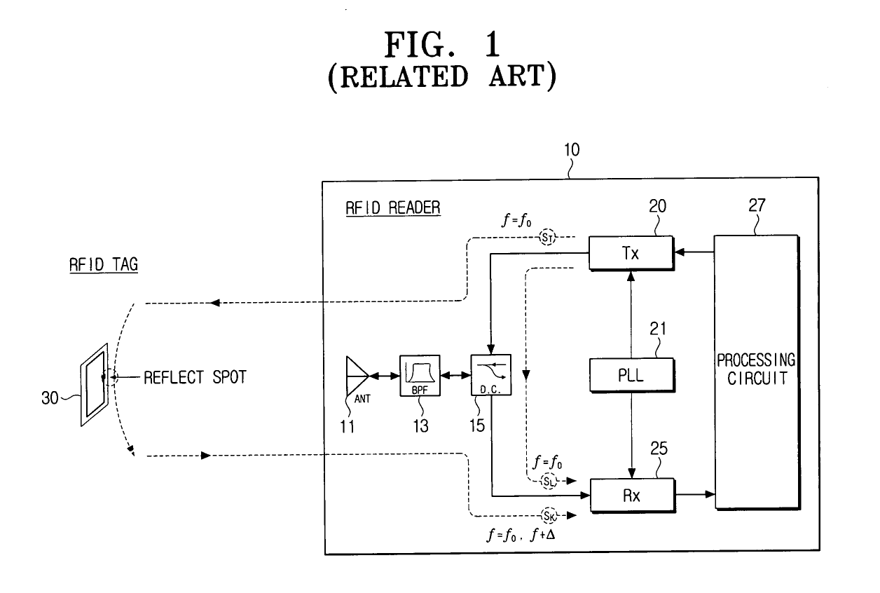

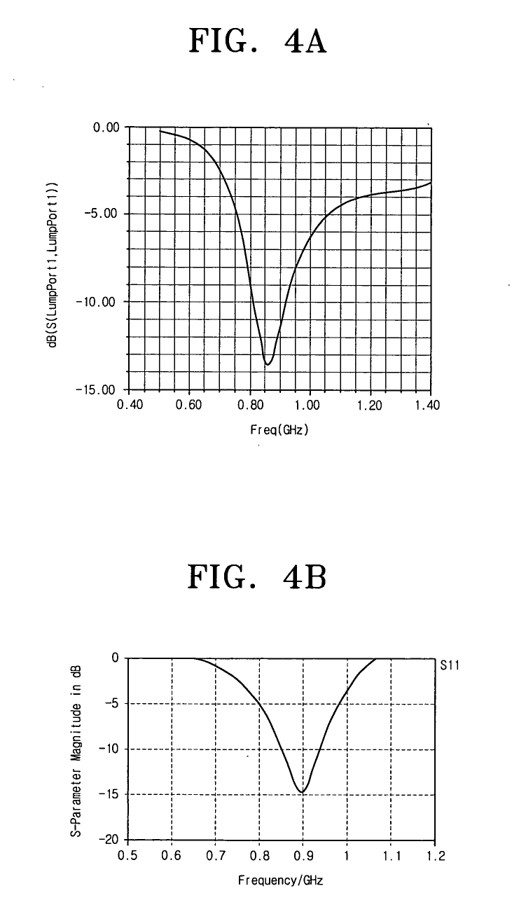

Meanwhile, a mobile communication terminal usually requires a matching circuit so that the antenna can operate at a desired operating frequency. As the recent improvements of antennas have enabled operation at a wide band frequency, a wideband antenna, which is able to operate not only at a frequency band of wireless mobile communication signal, but also at a frequency band of an RFID signal, is possible. Such a wide band antenna, when developed, will not need separate RFID matching circuits 20, 120 as shown in FIG. 2 or FIG. 4 for transmission and reception of RFID signals, but simply utilize the existing matching circuit. That is, the existing matching circuit can be utilized to operate as the RFID matching circuit as exemplified in FIG. 1.

Therefore, the wide band antenna such as whip antennas can satisfy both the communication band and the RFID band, without having to use the matching circuit.

The main antenna 110 is connected to one end of the ground 115. The ground 115 uses the substrate of the mobile communication terminal. The RFID reception antenna 120 is mounted to the other end of the ground 115.

The RFID reception antenna 120 uses a small antenna such as a chip ceramic antenna. The chip ceramic antenna is an effective replacement for the existing antennas, which can satisfy the current demands for miniaturization of mobile communications, GPS, and wireless computers. The chip ceramic antenna, which is a microstrip antenna formed of dielectric material, is printed with a silver electrode on a rear layer of the square ceramic substrate, and has a radiation electrode and a ground electrode. The chip ceramic antenna is more appropriate for the miniaturization and has more stable temperature than using a Teflon glass substrate.

The RFID reception antenna 120 may also be implemented as small size antennas such as PIFA/IFA type antennas.

By separately mounting the RFID reception antenna 120 using a small antenna such as chip ceramic antenna, input of RFID transmission carrier leakage to the RFID reception circuit can be prevented, and the size increase of mobile communication terminal can also be prevented.

FIG. 4A is a graphical representation of characteristic S11 of the main antenna of FIG. 2, and FIG. 4B is a graphical representation of characteristic S11 of the RFID reception antenna of FIG. 2.

More specifically, FIG. 4A shows an example when the main antenna 110 is used for mobile communication. That is, FIG. 4A shows characteristic S11 when the mobile communication matching circuit of FIG. 3 is operated. As shown, the main antenna forms a pole at 860 MHz, and forms the bandwidth of 815˜919 MHz of the mobile communication band with the center band of 860 MHz at −10 dB so that RFID wireless signal can be transmitted.

Meanwhile, as shown in characteristic S11 of FIG. 4B, the RFID reception antenna 120 forms a pole in 900 MHz, and includes bandwidth of 908.5˜914 MHz of the RFID communication band at −10 dB.

With characteristics S11 as shown in FIGS. 4A and 4B, the main antenna 110 may be used as an RFID transmission antenna, and the chip ceramic antenna may be used as the RFID reception antenna 120.

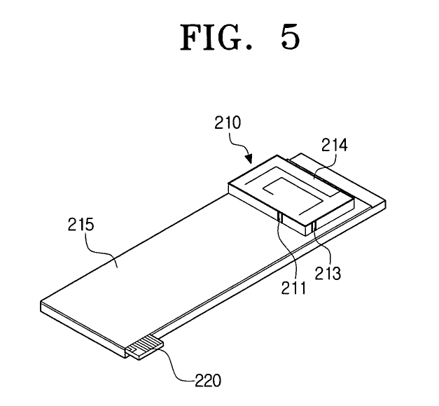

FIG. 5 is a perspective view of an antenna area of a mobile communication terminal according to a second exemplary embodiment of the present invention.

As in the first embodiment, the mobile communication terminal in this embodiment may include a main antenna 210, a ground 215, and an RFID reception antenna 220. The RFID reception antenna 220 may be implemented as a chip ceramic antenna. The main antenna 210 may be implemented as a planar inverted F antenna (PIFA), or a patch antenna, and FIG. 5 shows an example of using a PIFA.

The PIFA may have a three dimensional configuration formed of a ground 215, a radiating part 214, a feed part 211 and a short part 213.

The radiating part 214 is arranged on an upper end of the ground 215, and the short part 213 is formed on an end of the radiating part 214, with connecting the ground 215 and the radiating part 214. The feed part 211 supplies electric current to the radiating part 214. The impedance matching is usually determined by the position of the short part 213 and the length of the feed part 211.

The RFID matching circuit 70 and the communication matching circuit 80 as exemplified in FIG. 3 are applicable to the PIFA antenna.

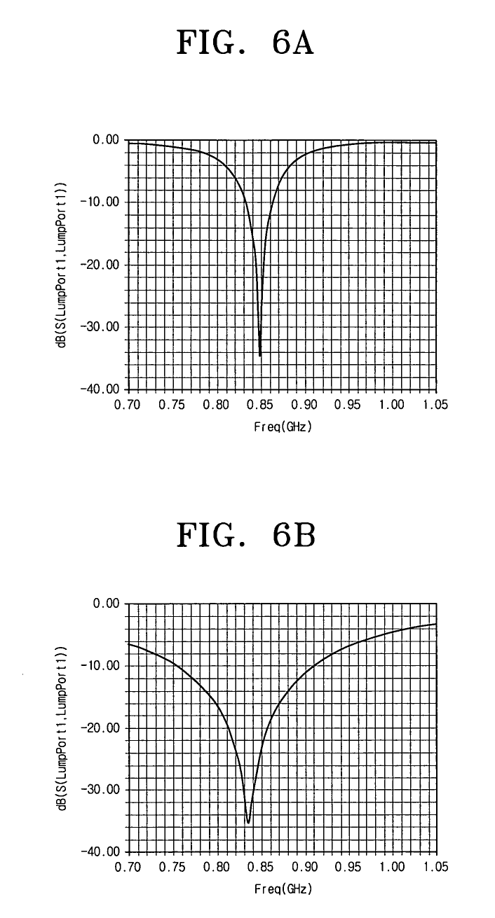

FIG. 6A is a graphical representation of characteristic S11 when the communication matching circuit of FIG. 3 is operated to enable transmission and reception of mobile communication wireless signal over the main antenna of FIG. 5, and FIG. 6B is a graphical representation of characteristic S11 when the RFID matching circuit of FIG. 3 is operated to enable transmission and reception of RFID wireless signal over the main antenna of FIG. 5.

As shown, FIG. 6A shows characteristics S11 which have pole formed in 850 MHz, and mobile communication band of 820˜875 MHz at −6 dB. FIG. 6B shows characteristic S11 which have pole formed in 835 MHz, and band of 755˜910 MHz at −10 dB.

The RFID reception antenna 220 of FIG. 5 may have the same characteristic S11 as shown in FIG. 4B.

Accordingly, the main antenna 210 of FIG. 5 is able to not only transmit and receive mobile communication wireless signal, but also transmit RFID transmission signal. Additionally, the RFID reception antenna 220 can receive RFID reception signal transmitted from the RFID tag.

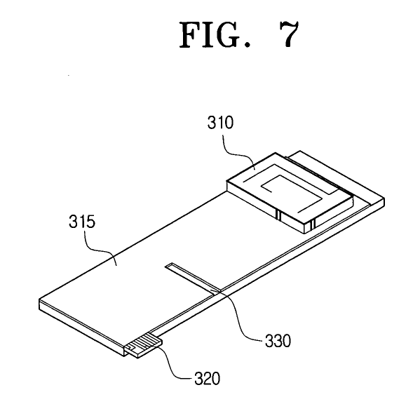

FIG. 7 is a perspective view of an antenna area of a mobile communication terminal according to a third exemplary embodiment of the present invention.

The mobile communication terminal may include a main antenna 310, a ground 315, and an RFID reception antenna 320. As in the embodiment shown in FIG. 5, the RFID reception antenna 320 in this embodiment may be implemented as a chip ceramic antenna, and the main antenna 310 may be implemented as a PIFA or a patch antenna.

The difference is that there is a slot 330 formed in the ground 315 between the main antenna 310 and the RFID reception antenna 320. The slot 330 is extended a predetermined width from a side of the ground 315 where the RFID reception antenna 320 is provided. The slot 330 is in linear configuration in this embodiment, but should not be construed as limiting. Accordingly, inter-coupling between the main antenna 310 and the RFID reception antenna 320, which is the signal ingress between the main antenna 310 and the RFID reception antenna 320, can be reduced due to the slot 330, and as a result, more accurate determination of wireless signal is possible.

The above exemplary embodiments have incorporated KR05-120707 by reference in explaining the combined construction of mobile communication antenna and RFID transmission antenna. Additionally, the combined construction of mobile communication antenna and RFID reception antenna may be exemplified. One will understand that a variety of ways can be employed to combine mobile communication antenna and RFID antenna, as well.

As described above, by separating an RFID transmission antenna from an RFID reception antenna, ingress of RFID transmission carrier leakage to the RFID reception circuit can be avoided. Furthermore, by using a small antenna such as a chip ceramic antenna for RFID reception, size of the mobile communication terminal, which would increase due to separation of the RFID reception antenna and the RFID transmission antenna, can be compact. Additionally, because the RFID transmission antenna is used also as the mobile communication antenna, the mobile communication terminal can be compact.

Meanwhile, because transmission carrier leakage is removed, the size of transmission signal can be greatly increased. As a result, dynamic range increases, without having to increase the sensitivity of the RFID tag, and communication distance between the mobile communication terminal and the RFID tag can be increased.

The above description is illustrative and not restrictive. Many variations of the invention will become apparent to those of skill in the art upon review of this disclosure. The scope of the invention should, therefore, be determined not with reference to the above description, but instead should be determined with reference to the appended claims along with their full scope.

What is claimed is:

1. A mobile communication terminal comprising a radio frequency identification (RFID) system to read information from an RFID tag arranged at a distance, the mobile communication terminal comprising:
an RFID transmission antenna which transmits or receives a wireless signal for mobile communication with a base station, and transmits a first RFID wireless signal to the RFID tag; and
an RFID reception antenna which receives a second RFID wireless signal transmitted from the RFID tag.

2. The mobile communication terminal of claim 1, wherein the RFID transmission antenna comprises at least one of a whip antenna, a planar inverted F antenna (PIFA), and a patch antenna.

3. The mobile communication terminal of claim 2, wherein the RFID transmission antenna is a main antenna and is also used as a mobile communication antenna to transmit and receive a mobile communication wireless signal.

4. The mobile communication terminal of claim 3, further comprising an RFID matching circuit which changes an operational band of the main antenna to a frequency band to transmit an output of the first RFID wireless signal; and
a communication matching circuit which matches the operational band of the main antenna to a frequency band for the mobile communication wireless signal.

5. The mobile communication terminal of claim 1, wherein the RFID reception antenna comprises a small size antenna.

6. The mobile communication terminal of claim 5, wherein the RFID reception antenna comprises a chip ceramic antenna which is formed of a dielectric substance.

7. The mobile communication terminal of claim 5, wherein the RFID receipt antenna comprises a small size antenna that is a type of a planar inverted-F antenna or an inverted-F antenna (PIFA/IFA).

8. The mobile communication terminal of claim 1, wherein the RFID transmission antenna and the RFID reception antenna are connected to a same ground.

9. The mobile communication terminal of claim 8, wherein a slot is extended from one side of the ground to remove coupling between the RFID transmission antenna and the RFID reception antenna.

10. The mobile communication terminal of claim 1, wherein the RFID reception antenna is provided separately from the RFID transmission antenna.

11. A mobile communication terminal comprising a radio frequency identification (RFID) system to read information from an RFID tag arranged at a distance, the mobile communication terminal comprising:
a RFID transmission antenna which transmits a first RFID wireless signal to the RFID tag; and
a RFID reception antenna which transmits or receives a wireless signal for mobile communication with a base station, and receives a second RFID wireless signal transmitted from the RFID tag.

12. The mobile communication terminal of claim 11, wherein the RFID reception antenna comprises at least one of a whip antenna, a planar inverted F antenna (PIFA), and a patch antenna.

13. The mobile communication terminal of claim 11, wherein the RFID reception antenna is a main antenna, and is also used as a mobile communication antenna to transmit and receive a mobile communication wireless signal.

14. The mobile communication terminal of claim 13, further comprising an RFID matching circuit which changes an operational band of the main antenna to a frequency band to receive an output of the second RFID signal; and
a communication matching circuit which matches the operational band of the main antenna to a frequency band for the mobile communication wireless signal.

15. The mobile communication terminal of claim 11, wherein the RFID transmission antenna comprises a small size antenna.

16. The mobile communication terminal of claim 15, wherein the RFID transmission antenna comprises a chip ceramic antenna which is formed of a dielectric substance.

17. The mobile communication terminal of claim 15, wherein the RFID transmission antenna comprises a small size antenna that is a type of a planar inverted-F antenna or an inverted-F antenna (PIFA/IFA).

18. The mobile communication terminal of claim 13, wherein the RFID transmission antenna and the RFID reception antenna are connected to a same ground.

19. The mobile communication terminal of claim 18, wherein a slot is extended from one side of the ground to remove coupling between the RFID transmission antenna and the RFID reception antenna.

20. The mobile communication terminal of claim 11, wherein the RFID transmission antenna is provided separately from the RFID transmission antenna.
